(19) United States
(12) Patent Application Publication
(10) Pub. No.: US 2026/0269179 A1
(43) Pub. Date: Sep. 10, 2026

(54) FARADAY APPARATUS AND ION IMPLANTER INCLUDING FARADAY APPARATUS

(71) Applicant: NISSIN ION EQUIPMENT CO., LTD., Koka-city (JP)

(72) Inventors: Hiroaki KAI, Koka-city (JP); Daiki TAKASHIMA, Koka-city (JP)

(73) Assignee: NISSIN ION EQUIPMENT CO., LTD., Koka-city (JP)

(21) Appl. No.: 19/539,852

(22) Filed: Feb. 13, 2026

(30) Foreign Application Priority Data
Mar. 6, 2025 (JP) 2025-035082

(51) Int. Cl. H01J 37/244; H01J 37/08; H01J 37/20; H01J 37/304; H01J 37/317

(52) U.S. Cl. CPC H01J 37/244; H01J 37/08; H01J 37/20; H01J 37/304; H01J 37/3171; H01J 2237/24535

(57) ABSTRACT

A faraday apparatus includes a mask having an opening through which an ion beam passes, a front plate that contacts the mask and has a first coolant flow path through which a coolant flows, a faraday cup disposed downstream of the front plate, and a back plate disposed downstream of the faraday cup and having a second coolant flow path through which a coolant flows. The front plate is disposed at a position at which the ion beam that is irradiated onto the mask does not irradiate the front plate.

### CROSS REFERENCE TO RELATED APPLICATION

This application is based on and claims priority from Japanese Patent Application No. JP 2025-035082 on March 6, 2025 in the Japan Patent Office, the contents of which being incorporated by reference herein in its entirety.

### BACKGROUND

### Field

The present disclosure relates to a faraday apparatus used for measuring a beam current of an ion beam and to an ion implanter including the faraday apparatus.

### Description of Related Art

A faraday apparatus comprising a faraday cup is used for measuring a beam current of an ion beam. When the ion beam is irradiated during measurement, a temperature of the faraday cup may become high. Therefore, the faraday apparatus may include a cooling means for cooling the faraday cup.

### SUMMARY

According to an aspect of one or more embodiments, a faraday apparatus may include a mask having an opening through which an ion beam passes; a front plate that contacts the mask and has a first coolant flow path through which a coolant flows; a faraday cup disposed downstream of the front plate; and a back plate disposed downstream of the faraday cup and having a second coolant flow path through which a coolant flow. The front plate may be disposed at a position at which the ion beam that is irradiated onto the mask does not irradiate the front plate.

According to another aspect of one or more embodiments, a faraday apparatus may include a mask having a plurality of openings through which an ion beam passes; a front plate that contacts the mask, has a plurality of holes that correspond respectively to the plurality of openings, and has a first coolant flow path through which a coolant flows; a plurality of faraday cups that correspond respectively to the plurality of openings and that are disposed downstream of the front plate; and a back plate that are disposed downstream of the plurality of faraday cups and that have a second coolant flow path through which a coolant flows. The front plate is entirely covered by the mask

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates an example of a schematic view of an ion implanter, according to some embodiments;

FIG. 2 illustrates an example of a schematic view of a faraday apparatus as viewed from a Z-axis direction, according to some embodiments;

FIG. 3 illustrates an example of a perspective view taken along line A-A in FIG. 2;

FIG. 4 illustrates an example of a cross-sectional view taken along line B-B in FIG. 2;

FIG. 5 illustrates an example of a schematic view of a configuration of a front plate, according to some embodiments;

FIG. 6 illustrates an example of a schematic view of a configuration of a back plate, according to some embodiments; and

FIG. 7 illustrates an example of a perspective view of another configuration of a faraday apparatus, according to some embodiments.

### DETAILED DESCRIPTION

Hereinafter, various embodiments of the present disclosure will be described with reference to the drawings. In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly. In the following embodiments, “downstream” refers to a direction of ion beam travel with respect to an object.

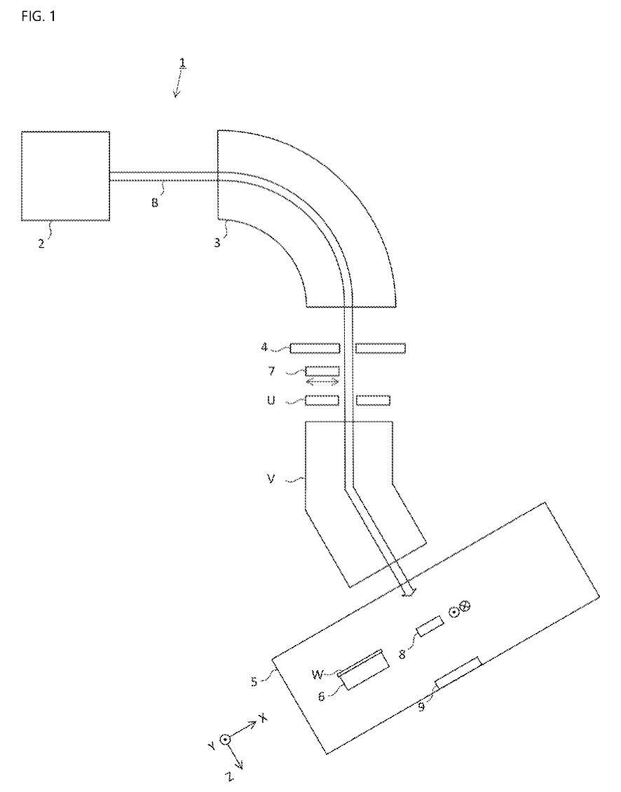

FIG. 1 illustrates an example configuration of an ion implanter 1, according to some embodiments. The ion implanter 1 includes an ion source 2, an analyzing electromagnet 3, an analyzing slit 4, a first faraday apparatus 7, a uniformizing lens U, a beam deflector V, and a process chamber 5.

The Z-axis direction is a travel direction of an ion beam B transported to the process chamber 5. The X-axis direction and the Y-axis direction are respectively orthogonal to the Z-axis direction. In a cross-section of the ion beam B in the XY plane, a dimension of the ion beam B in the Y-axis direction is longer than that in the X-axis direction. Such an ion beam B may be referred to as a ribbon beam.

An ion beam B extracted from the ion source 2 may be mass-analyzed by the analyzing electromagnet 3 and the analyzing slit 4, and then transported to the process chamber 5. The uniformizing lens U may locally adjust the travel direction of the ion beam B in the Y- axis direction, which is the longitudinal direction of the ion beam B, by a magnetic field or an electric field, thereby adjusting uniformity of a beam current density distribution in the Y-axis direction. The dimension of the ion beam B in the Y-axis direction may be longer than a diameter of a wafer W, which is substantially circular in plain view. The beam deflector V may accelerate or decelerate the mass-analyzed ion beam B while deflecting the ion beam B. For example, such a beam deflector V may include a plurality of electrostatic lenses arranged along the ion beam transport path.

In the process chamber 5, the wafer W may be supported by a platen 6 and may be reciprocally scanned in a direction parallel to the X-axis by a drive mechanism (not shown). When the wafer W is reciprocally scanned, the ion beam B is irradiated across an entire surface of the wafer W, and an ion implantation process is performed on the wafer W. The wafer W may be, for example, a semiconductor wafer such as silicon or silicon carbide. However, a glass substrate or another substrate may also be used as the wafer W, and the type of wafer W is not limited to these types.

The scanning direction of the wafer W described above is an example, and the scanning direction is not necessarily required to be parallel to the X-axis direction. Any direction intersecting the Z-axis direction, which is the travel direction of the ion beam B, may be used.

The ion implanter 1 may include the first faraday apparatus 7, a second faraday apparatus 8, and a third faraday apparatus 9 for measuring a beam current of the ion beam B in the ion beam transport path and the process chamber 5. The number, arrangement, and function of the faraday apparatuses may vary depending on the configuration and function of the ion implanter 1. The following describes examples of use of the faraday apparatus.

For example, the first faraday apparatus 7 may be moved in a direction of an arrow by a drive mechanism (not shown). Before an ion implantation process is performed on the wafer W, extraction of the ion beam B from the ion source 2 may be started. At this time, the first faraday apparatus 7 may be moved to a position at which the ion beam B is irradiated onto the first faraday apparatus 7.

Based on a measurement result of the first faraday apparatus 7, parameters of the ion source 2 and the analyzing electromagnet 3 may be adjusted, and a setup of the ion beam B may be performed. After completion of the setup of the ion beam B, the first faraday apparatus 7 may be retracted from the position at which the ion beam B is irradiated onto the first faraday apparatus 7.

For example, the second faraday apparatus 8 may be moved in a direction parallel to the Y-axis by a drive mechanism (not shown). Before an ion implantation process is performed on the wafer W, the second faraday apparatus 8 may be moved to a position at which the ion beam is irradiated onto the second faraday apparatus 8, and measurement of the beam current may be started. Thereafter, the second faraday apparatus 8 may be moved along the Y-axis direction, which is the longitudinal direction of the ion beam B, while measuring the beam current.

Based on a measurement result of the second faraday apparatus 8, parameters of the uniformizing lens U may be changed, and uniformity of the beam current density distribution in the longitudinal direction of the ion beam B may be adjusted. After measurement by the second faraday apparatus 8 is completed, the second faraday apparatus 8 may be moved to a position that does not interfere with scanning of the wafer W.

For example, the third faraday apparatus 9 may be a fixed faraday apparatus and may be disposed at a position in the process chamber 5 at which the ion beam B is irradiated onto the third faraday apparatus 9. During the ion implantation process, the ion beam B may be irradiated onto the third faraday apparatus 9 before and after the wafer W crosses the ion beam B. During the ion implantation process, the third faraday apparatus 9 may periodically measure the beam current of the ion beam B and monitor a state of the ion beam B.

In order to implant a target dose into the wafer W, the third faraday apparatus 9 may measure the beam current before starting the ion implantation process. The ion implanter 1 may include a controller (not shown). The controller may calculate a change amount of the beam current from the beam current measured before starting ion implantation and the beam current measured during ion implantation. Thereafter, the controller may calculate a new scanning speed for scanning the wafer W based on the calculated change amount of the beam current. The drive mechanism may scan the wafer W based on the new scanning speed.

As described above, the scanning speed of the wafer W may be changed according to a fluctuation of the beam current during ion implantation process, so that the implanted dose into the wafer W may be controlled to reach the target dose.

The following describes a specific configuration of the third faraday apparatus 9 as a representative of the first faraday apparatus 7, the second faraday apparatus 8, and the third faraday apparatus 9. In other words, the following description may also apply to the other faraday apparatuses (e.g., the first faraday apparatus 7 and the second faraday apparatus 8).

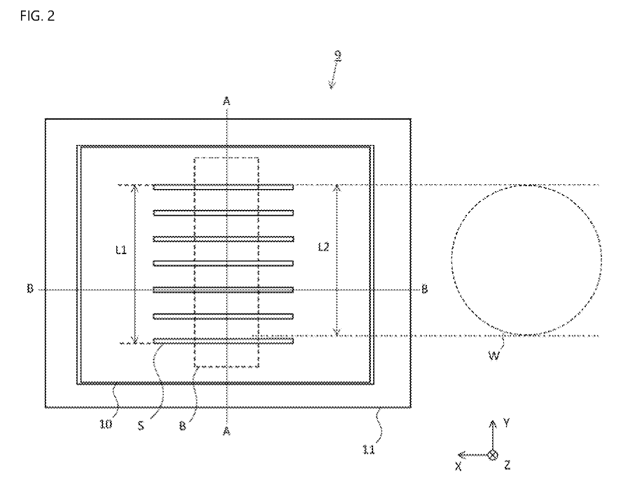

FIG. 2 illustrates a schematic view of the third faraday apparatus 9, according to an embodiment. The third faraday apparatus 9 includes a flange 11 forming an outer frame of the third faraday apparatus 9 and a plurality of members disposed inside the flange 11. For example, the plurality of members may include a mask 10, a front plate 16, suppression electrodes 15, faraday cups 14, insulating members 13, and a back plate 12, in this order. Of the plurality of members, the mask 10 having a plurality of openings S is disposed at a frontmost side (e.g. a side facing the ion beam B) of the plurality of members in the Z-axis direction. The openings S may be slits elongated in one direction, but embodiments are not limited thereto. In some embodiments, the opening may be a plurality of round or square holes.

The mask 10 may be irradiated with the ion beam B. The plurality of openings S formed in the mask 10 are arranged in the Y-axis direction, which is the longitudinal direction of the ion beam B, and are spaced apart from each other in the Y-axis direction. A distance L1 between outermost edges of the openings S at outermost ends arranged in the Y-axis direction is longer than a region L2 of a portion of the ion beam B that is irradiated onto the wafer W. This longer distance enables measurement of the beam current density distribution in the region of the ion beam B irradiated onto the wafer W.

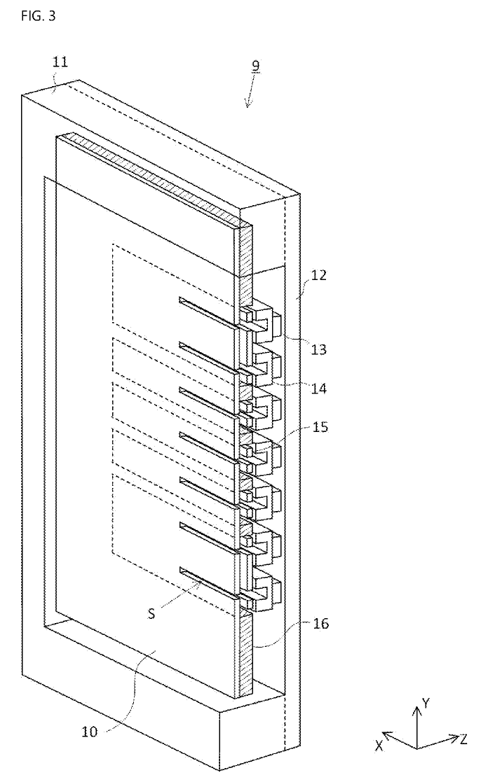

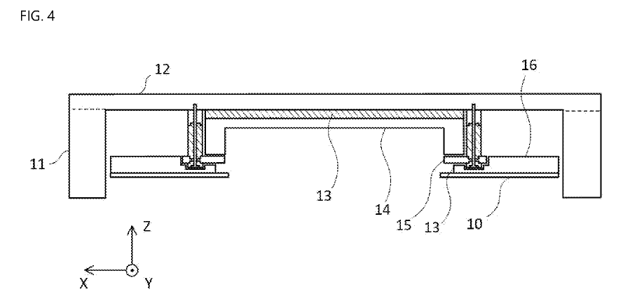

FIG. 3 illustrates a perspective view of the third faraday apparatus 9 taken along line A-A in FIG. 2, according to some embodiments. In FIG. 3, for convenience of visualizing an internal structure of the third faraday apparatus 9, the upper part of the flange 11 is shown as transparent. FIG. 4 illustrates a cross-sectional view of the third faraday apparatus 9 taken along line B-B in FIG. 2, according to some embodiments. The details of the third faraday apparatus 9 are described with reference to FIGS. 3 and 4.

The front plate 16 (the hatched member in FIG. 3) for cooling the mask 10 is disposed in contact with a rear surface of the mask 10. A coolant flow path (not shown) is formed in the front plate 16. A coolant, for example, pure water, flows through the coolant flow path.

With the above configuration, thermal deformation of the mask 10 due to irradiation of a high beam current ion beam B may be prevented. In addition, in the travel direction of the ion beam B, the entire front plate 16 is covered by the mask 10. In other words, the front plate 16 is disposed at a position invisible from the ion beam B irradiated onto the mask 10 (i.e., such that the ion beam B that is irradiated onto the mask 10 does not irradiate the front plate 16).The ion beam B irradiated onto the mask 10 refers to the ion beam B before passing through the openings S of the mask 10, and not the ion beam B after passing through the openings S of the mask 10.

If the front plate 16 is positioned in a location visible from the ion beam B, there is a concern that the ion beam B may irradiate the front plate 16 in the event of a deviation in the travel direction of the ion beam. If the ion beam B is irradiated onto the front plate 16, the coolant in the coolant flow path formed in the front plate 16 may be heated, resulting in insufficient cooling of the mask 10. In addition, the heated coolant may become vapor, increasing the pressure in the coolant flow path and possibly causing failure of the front plate 16.

However, if the front plate 16 is completely covered by the mask 10 as viewed from the travel direction of the ion beam B, the above concerns may be resolved. In addition, the mask 10 may be sputtered by irradiation with the ion beam B. The mask 10 may be increasingly consumed by sputtering over time, and at some point, replacement of the mask 10 may be required. If the coolant flow path is formed in the mask 10, replacement of the mask 10 requires the supply of coolant to the mask 10 be stopped and measures taken to prevent water leakage when replacing the mask 10. However, in the configuration according to some embodiments shown in FIGS. 3 and 4, since the mask 10 and the front plate 16 having the coolant flow path are separate members, it is not necessary to take measures against water leakage when replacing the mask 10. This configuration allows easy replacement of the mask 10.

Furthermore, if the front plate 16 is disposed at a position visible from the ion beam B irradiated onto the mask 10, various particles floating in the ion beam transport path may easily deposit on the front plate 16. If the ion beam B is irradiated onto the deposits on the front plate 16, the deposits may be sputtered by the ion beam B and scatter downstream. If the sputtered particles scattered downstream are mixed into the wafer W being processed, manufacturing defects of the wafer W may occur. However, in the configuration according to some embodiments shown in FIGS. 3 and 4, since the front plate 16 is disposed at a position invisible from the ion beam B irradiated onto the mask 10 (i.e., the front plate 16 is completely covered by the mask 10), deposition of floating matter on the front plate 16 is prevented.

Downstream of the front plate 16, the faraday cup 14 is disposed at a position corresponding to each opening S. When the ion beam B passes through the openings S of the mask 10 and is irradiated onto the faraday cup 14, secondary electrons may be emitted from the faraday cup 14. In the vicinity of the rear surface of the openings S, suppression electrodes 15 are disposed between portions of the front plate 16 arranged in the Y-axis direction. The suppression electrodes 15 may prevent secondary electrons emitted from corresponding ones of the faraday cups 14 from flowing out of the faraday cup 14.

In the configuration shown in FIGS. 3 and 4, a permanent magnet may be disposed instead of the suppression electrodes 15 for the purpose of preventing outflow of secondary electrons. The permanent magnet may be disposed at the same position as the suppression electrodes 15 and may generate a magnetic field along the Y-axis direction near the entrance of the faraday cups 14.

The flange 11 includes the back plate 12. The back plate 12 is disposed downstream of the faraday cups 14, and the back plate 12 and the faraday cups 14 may be in thermal contact by points or surfaces in the opposing direction of the back plate 12 and the faraday cups 14. A coolant flow path (not shown) may be formed in the back plate 12. A coolant, for example pure water, flows through the coolant flow path.

The insulating member 13 is disposed between each of the faraday cups 14 and the back plate 12. An example of the insulating member 13 may be aluminum nitride or aluminum oxide, which has high thermal conductivity.

In some embodiments, a heat-resistant elastic member such as silicone rubber or fluororubber may be provided between the insulating member 13 and the back plate 12. By providing such an elastic member, adhesion between the insulating member 13 and the back plate 12 may be improved, and the cooling effect of the back plate 12 on the faraday cup 14 may be enhanced. In addition, metal powders such as silver, copper, or aluminum may be added to the elastic member to improve the thermal conductivity of the elastic member.

Since the back plate 12 and the faraday cups 14 are in thermal contact, the back plate 12 may sufficiently cool the faraday cup 14. When the ion beam B is irradiated onto the third faraday apparatus 9, the faraday cup 14 may become somewhat high in temperature, and the surroundings of the faraday cup 14 may be heated by radiant heat transfer. However, since the back plate 12 is disposed downstream of the faraday cup 14 and the front plate 16 is disposed upstream of the faraday cup 14, radiant heat transfer from the faraday cup 14 may be absorbed by the front plate 16 and the back plate 12, thereby suppressing an increase in temperature around the faraday cup 14.

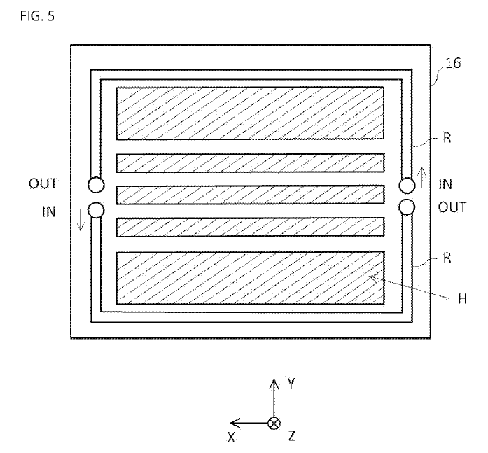

FIG. 5 illustrates an example configuration of the front plate 16, according to some embodiments. The front plate 16 may have holes H at locations corresponding to the openings S and the suppression electrodes 15. It is noted that the front plate 16 is shown with cross-hatching in FIG. 3, whereas in FIG. 5, the holes H are illustrated with cross-hatching to aid in discerning the holes H. The holes H in FIG. 5 correspond to the dashed lines in FIG. 3. Above and below a center of the front plate 16, two coolant flow paths R are formed. In the two coolant flow paths R, the coolant may circulate counterclockwise. By configuring the circulation direction of the coolant as shown, a temperature difference in the front plate 16 in the X-axis direction may be reduced. In some embodiments, the direction of the coolant in each coolant flow path R may be clockwise. The coolant flow path R shown in FIG. 5 is an example, and a coolant flow path may be formed between adjacent ones of the holes H, for example. The number of coolant flow paths R is not limited to two, and may be one or three or more.

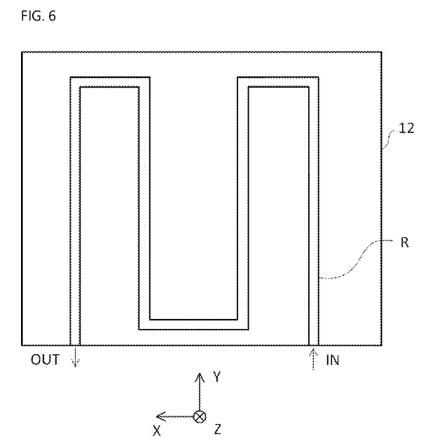

FIG. 6 illustrates an example configuration of the back plate 12, according to some embodiments. The back plate 12 may have a crank-shaped coolant flow path R that is bent in the X-Y plane. The coolant flow path R shown in FIG. 6 is an example, and the number of bends in the coolant flow path R may be increased, and the coolant flow path R may be formed more densely over the entire surface of the back plate 12. The number of coolant flow paths R is not limited to one, and may be two or more.

The back plate 12 may be provided as a part of the flange 11, or may be provided as a separate member from the flange 11. For example, as viewed from the travel direction of the ion beam B, a flange having a rectangular shape may be prepared, and a plate-shaped back plate 12 may be attached to the rear surface thereof.

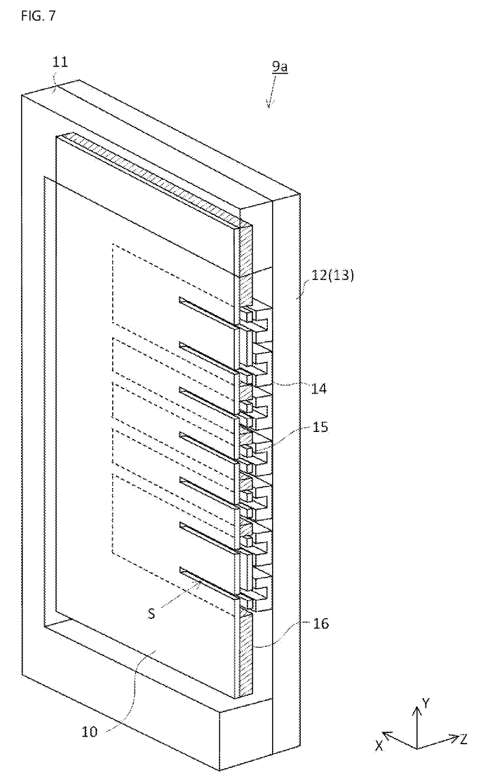

FIG. 7 illustrates an example of the third faraday apparatus 9, according to some embodiments. In the third faraday apparatus 9a shown in FIG. 7, separate insulating members 13 are omitted, and the back plate 12 is formed of the insulating member 13 such as aluminum oxide, and a coolant flow path (not shown) is formed in the back plate 12 formed of the insulating member 13. In some embodiments, there may be two layers including the back plate 12 and the insulating member 13 such that, in contrast to the example of FIGS. 3 and 4, the insulating member 13 may be provided that substantially covers the back plate 12. In some embodiments, as in FIGS. 3 and 4, a heat-resistant elastic member such as silicone rubber or fluororubber may be provided between the insulating member 13 and the back plate 12 to improve adhesion between the insulating member 13 and the back plate 12. The heat-resistant elastic member may also be provided between the faraday cup 14 and the back plate 12.

In the embodiments shown in FIGS. 2 to 7, the configuration of the faraday apparatus has been described mainly with reference to the third faraday apparatus 9, 9a, but the same configuration may be applied to the first faraday apparatus 7 and the second faraday apparatus 8. That is, in the first faraday apparatus 7 and the second faraday apparatus 8, a front plate for cooling the mask may be provided on the rear side of the mask and the front plate may be in contact with the mask, and the rear side of the faraday cup disposed downstream of the front plate may be cooled by the back plate. At this time, the front plate 16 may be disposed at a position invisible from the ion beam B irradiated onto the mask 10. In addition, cooling by the back plate may be performed not only on the rear surface of the faraday cup but also on the side surface of the faraday cup.

The configuration of the ion implanter 1 shown in FIG. 1 is merely an example, and two or fewer or four or more faraday apparatuses may be provided. When a plurality of faraday apparatuses are provided, the disclosed embodiments do not need to be applied to all the faraday apparatuses, and it is sufficient to apply the disclosed embodiments to the faraday apparatuses that require countermeasures against high temperature. In the ion implanter 1 shown in FIG. 1, the third faraday apparatus 9 is a fixed faraday apparatus and is irradiated with the ion beam B during ion implantation process. Such a faraday apparatus is irradiated with the ion beam B for a long time and is likely to become high in temperature. Therefore, it is advantageous to apply the disclosed embodiments to the third faraday apparatus 9.

The ion beam B shown in FIG. 1 is a ribbon beam elongated in the Y-axis direction, but the cross-section of the ion beam may be a spot-shaped ion beam having a small elliptical shape, and the spot-shaped ion beam may be scanned in a direction parallel to the Y-axis direction by a magnetic field or an electric field. In this case, the ion implanter 1 may include a scanner for scanning the ion beam and a collimator for making the scanned ion beam into a parallel beam.

In general, a ribbon beam may have a higher beam current than a spot-shaped ion beam. Therefore, it is advantageous to apply the disclosed embodiments to an ion implanter that handles a ribbon beam.

In the ion implanter 1 shown in FIG. 1, the analyzing electromagnet 3 and the analyzing slit 4 are provided. However, the configuration of the ion implanter 1 may be a so- called non-mass-analyzing type that may omit the analyzing electromagnet 3 and the analyzing slit 4.

In the ion implanter 1 shown in FIG. 1, the energy of the ion beam B implanted into the wafer W is determined by acceleration or deceleration in the beam deflector V. The higher the energy of the ion beam B, the more likely the faraday cup is to become high in temperature. It is advantageous to apply the disclosed embodiments to an ion implanter including an optical element such as the beam deflector V that converts the energy of the ion beam B to a higher energy in the ion beam transport path.

In the above-described embodiments, it is advantageous that the back plate 12 and the front plate 16 are made of a material having high thermal conductivity, such as gold, silver, copper, aluminum, or an alloy containing these metals.

It should be understood that embodiments are not limited to the various embodiments described above, but various other changes and modifications may be made therein without departing from the spirit and scope thereof as set forth in appended claims.

What is claimed is:

1. A faraday apparatus comprising:
a mask having an opening through which an ion beam passes;
a front plate that contacts the mask and has a first coolant flow path through which a coolant flows;
a faraday cup disposed downstream of the front plate; and
a back plate disposed downstream of the faraday cup and having a second coolant flow path through which a coolant flows,
wherein the front plate is disposed at a position at which the ion beam that is irradiated onto the mask does not irradiate the front plate.

2. The faraday apparatus according to claim 1, wherein the back plate and the faraday cup are in thermal contact.

3. The faraday apparatus according to claim 1, further comprising a suppression electrode disposed between the front plate and the faraday cup, the suppression electrode suppressing emission of secondary electrons from the faraday cup.

4. The faraday apparatus according to claim 1, wherein the mask and the front plate are separate members, and the front plate cools the mask by contact.

5. The faraday apparatus according to claim 1, wherein the opening comprises a plurality of openings that are spaced apart from each other, and
wherein the faraday cup comprises a plurality of faraday cups corresponding respectively to the plurality of openings.

6. The faraday apparatus according to claim 1, wherein at least one of the front plate or the back plate is made of a material having high thermal conductivity.

7. The faraday apparatus according to claim 1, further comprising an insulator disposed between the faraday cup and the back plate.

8. The faraday apparatus according to claim 7, wherein the insulator is made of aluminum nitride or aluminum oxide.

9. The faraday apparatus according to claim 7, further comprising a heat-resistant elastic member disposed between the insulator and the back plate.

10. The faraday apparatus according to claim 1, further comprising a heat-resistant elastic member disposed between the faraday cup and the back plate.

11. The faraday apparatus according to claim 1, wherein the front plate has a hole corresponding to the opening in the mask.

12. An ion implanter comprising:
a process chamber comprising the faraday apparatus according to claim 1, the process chamber being configured to receive an object to be irradiated with the ion beam; and
an ion source configured to extract the ion beam.

13. The ion implanter according to claim 12, wherein the faraday apparatus is disposed downstream of a position at which the object is received and at a position at which the ion beam is irradiated on the faraday apparatus.

14. The ion implanter according to claim 12, wherein the ion beam is a ribbon beam.

15. The ion implanter according to claim 12, wherein in the process chamber, the object is scanned in a direction intersecting a travel direction of the ion beam, and the faraday apparatus has a dimension larger than the object to be irradiated in a direction orthogonal to both the travel direction the ion beam and a scanning direction of the object.

16. An ion implanter comprising:
the faraday apparatus according to claim 1,
wherein the faraday apparatus is disposed at a position at which the ion beam is irradiated onto the faraday apparatus during an ion implantation process.

17. An ion implanter comprising:
the faraday apparatus according to claim 1,
wherein the faraday apparatus is disposed at a position at which the ion beam is not irradiated during an ion implantation process.

18. A faraday apparatus comprising:
a mask having a plurality of openings through which an ion beam passes;
a front plate that contacts the mask, has a plurality of holes that correspond respectively to the plurality of openings, and has a first coolant flow path through which a coolant flows;
a plurality of faraday cups that correspond respectively to the plurality of openings and that are disposed downstream of the front plate; and
a back plate that are disposed downstream of the plurality of faraday cups and that have a second coolant flow path through which a coolant flows,
wherein the front plate is entirely covered by the mask.
